(19) United States
(12) Patent Application Publication
(10) Pub. No.: US 2004/0060722 A1
(43) Pub. Date: Apr. 1, 2004

(54) Retention device and electrical connector having the same

(76) Inventors: Rajagopalan Chandrasekhar, Huntington Beach, CA (US); Dennis B. Jones, Orange, CA (US)

Correspondence Address: WEI TE CHUNG, FOXCONN INTERNATIONAL, INC., 1650 MEMOREX DRIVE, SANTA CLARA, CA, 95050, US

(21) Appl. No.: 10/256,731

(22) Filed: Sep. 27, 2002

(51) Int. Cl. H02G 3/08; H05K 5/00

(52) U.S. Cl. 174/52.1

(57) ABSTRACT

A boardlock (10, 10′) for securely mounting an electrical connector (1, 1′) onto a board (9, 9′) includes a housing retention portion (20), a pair of arms (30) extending from the housing retention portion, and a pair of legs (40) projecting from the arms and extending away from each other. The pair of arms each have a bowed portion (32) formed at respective distal ends thereof and the bowed portion is configured as a bow. The pair of legs each form a tip portion (41) for abutting against a bottom of the board. A diameter of a hole (91, 91′) of the board, in which the boardlock is received, is larger than a distance between the two tip portions of the legs, while smaller than a distance between the two bowed portions.

### BACKGROUND OF THE INVENTION

1. Field of the Invention

The present invention generally relates to a retention device, and particularly to a retention device for use in electrical board mounted connectors.

2. Description of Prior Arts

Board mounted electrical connectors are typically connected to a printed circuit board either by surface mount technology or soldered through hole connections which may be accomplished through wave soldering techniques. In either instance, it is necessary to first accurately position the electrical connector so that its contacts engage complimentary contact surfaces on the printed circuit board, then temporarily hold the electrical connector in place, and finally form the electrical connections by SMT, wave soldering, or any other suitable method.

The step of temporally holding the connector in place over the contact interface is typically accomplished by a holding device which is incorporated into the housing of the electrical connector. These holding devices may be integrally molded into the housing or may be separate metal boardlocks which are fixed to the housing as shown in U.S. Pat. No. 5,336,111 ('111 patent) issued on Aug. 9, 1994 and U.S. Pat. No. 5,989,064 ('064 patent) issued on Nov. 23, 1999, both of which are issued to the Whitaker Corporation. These boardlocks serve several purposes. First, they extend from the mounting face of the housing beyond the contact tails so that they engage openings in the printed circuit board first to insure that the connector is properly aligned for the tails to pass through the contact openings in the circuit board without being damaged. Secondly, once inserted into the openings of the circuit board, the boardlocks serve to hold the connector such that the mounting face of the housing remains flush or in engagement with the printed circuit board along its entire length.

A separate metal boardlock disclosed in both '111 patent and '064 patent features a plurality of arms extending from a housing securing portion and the arms are jointed together by integral neck portions so that a hole is surrounded by the arms and the neck portions. Once the boardlock is inserted into the opening of the printed circuit board, it is first elastically deformed. It then experiences plastic deformation as it is urged further into the opening to its final securing position. As a result, the plastic deformation of the boardlock is necessarily required in order to firmly secure the boardlock in the opening. Moreover, a large initial insertion force is also required when inserting such boardlock into the opening. Further, such a boardlock cannot be firmly retained in the opening for the retention force is provided by frictional force occurred between the boardlock and the inner wall of the opening, and by the deformation of the boardlock.

Similarly, U.S. Pat. No. 5,462,454, which is another patent issued to the Whitaker Corporation on Oct. 31, 1995, introduces such a boardlock that a deformable bridge portion of the boardlock achieves a permanent plastic deformation through the use of a die. The die has a convex bottomed surface in order to arc the deformed bridge portion towards the printed circuit board in order to enhance the mechanical resistance of the boardlock with respect to an upwards pulling force thereon. Obviously, the employment of the die not only complicates the procedure for securely mounting an electrical connector on a printed circuit board but increases the assembly cost.

Another kind of boardlock which is commonly used in the art, can be found in U.S. Pat. No. 4,907,987 issued to AMP Incorporated on Mar. 13, 1990 and U.S. Pat. No. 5,419,713 issued to Berg Electronics on May 30, 1995. Both patents disclose a boardlock having barbs thereon interfering with and thus securing the boardlock within the opening of the printed circuit board. However, each boardlock of the two patents needs a relatively large insertion force so as to firmly mount the electrical connector on the printed circuit board.

Hence, an improved boardlock is desired to overcome the disadvantages of the prior art.

### BRIEF SUMMARY OF THE INVENTION

Accordingly, a first object of the present invention is to provide an improved boardlock for fixedly secure an electrical connector on a printed circuit board without initial insertion force.

a second object of the present invention is to provide an improved boardlock which has overall rigidity for firmly securing an electrical connector on a printed circuit board while without any plastic deformation.

In order to achieve the above-mentioned objects, a boardlock for securely mounting an electrical connector onto a printed circuit board includes a housing retention portion, a pair of arms extending from the housing retention portion, and a pair of legs projecting from the arms and extending away from each other. The pair of arms each have an elastic portion formed at respective distal ends thereof and the elastic portion is configured as a bow. The pair of legs each form a tip portion for abutting against a bottom of the printed circuit board. A distance between the two arms is larger than a diameter of a hole of the board, in which a boardlock is received.

Other objects, advantages and novel features of the invention will become more apparent from the following detailed description of the present embodiment when taken in conjunction with the accompanying drawings.

### BRIEF DESCRIPTION OF THE DRAWINGS

FIG. 1 is an exploded, perspective view of a connector assembly in accordance with the present invention;

FIG. 2 is an enlarged, perspective view of a boardlock shown in FIG. 1;

FIG. 3 is an enlarged, cross-sectional view of the boardlock and a part of the connector that the boardlock is assembled to;

FIG. 4 is an enlarged, cross-sectional view of the boardlock, a part of the connector that the boardlock is assembled to, and a part of a printed circuit board having a hole in which the boardlock is partially received;

FIG. 4A is partial enlarged view of the boardlock shown in FIG. 4;

FIG. 5 is a view similar to FIG. 4 while the boardlock is urged further into the hole of the printed circuit board;

FIG. 6 is a view similar to FIG. 4 while the boardlock is substantially received in the hole of the printed circuit board;

FIG. 7 is an exploded, perspective view of a connector assembly in accordance with an alternative embodiment of the present invention; and

FIG. 8 is a front view of the connector shown in FIG. 7;

### DETAILED DESCRIPTION OF THE INVENTION

Reference will now be made to the drawing figures to describe the present invention in detail.

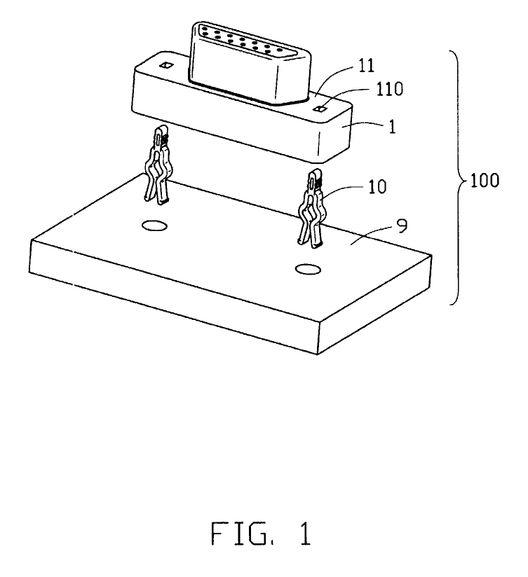

With reference to FIG. 1, a connector assembly 100 in accordance with a first embodiment of the present invention comprises an electrical connector 1 and a printed circuit board 9 on which the electrical connector 1 is mounted. The electrical connector 1 has an elongated, insulating housing 11 defining a pair of boardlock receiving holes 110 passing from a top face to a bottom face for receiving two boardlocks 10.

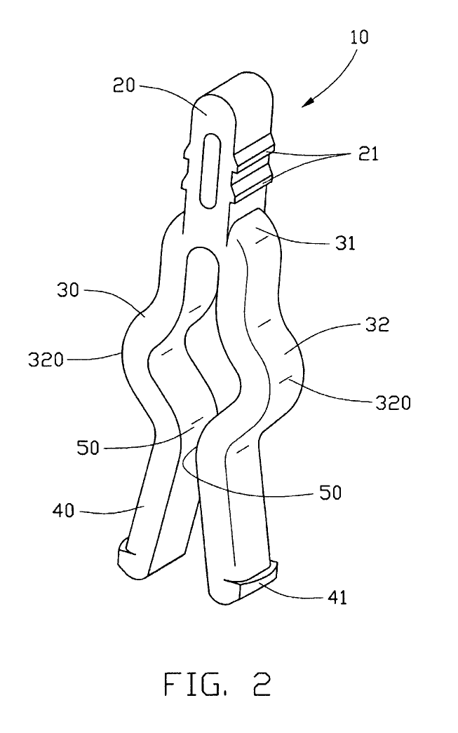

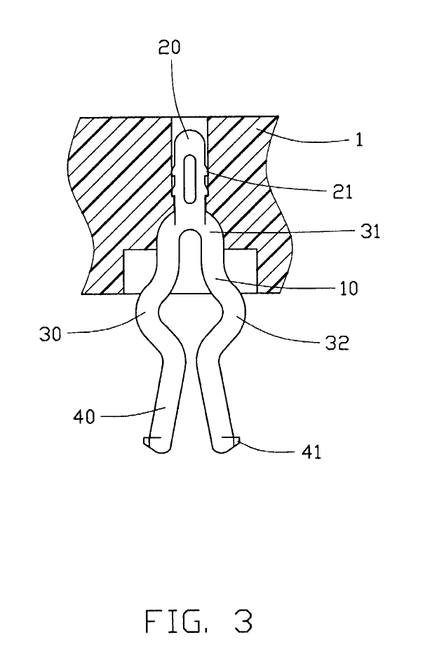

As show in FIG. 2, the two boardlocks 10 are made from elastic material and each comprises a housing retention portion 20, a pair of arms 30 extending from the housing retention portion 20 and a pair of legs 40 respectively protruding from the arms 30. The housing retention portion 20 of the boardlock 10 has a plurality of barbs 21 disposed along opposite sides of the housing retention portion 20 for retaining the boardlock 10 in a corresponding boardlock receiving hole 11. Particularly, FIG. 3 shows the boardlock 10 which has been firmly assembled in the boardlock receiving hole 11.

Continuing to FIG. 2, the pair of arms 30 each has a shoulder 31 and a bowed portion 32 extending from the shoulder 31. The shoulders 31 project oppositely from the housing retention portion 20 at an angle from each other. The bowed portions 32 are configured as a bow and respectively form an outer curved surface 320 along outer faces of the bowed portions 32. The pair of legs 40 oppositely extend from the corresponding bowed portions 32 of the arms 30 along an angle from each other. The legs 40 has a pair of tip portions 41 protruding outwardly from opposite distal ends of the legs 40. There are two inner curved surfaces 50 further defined on opposed inner faces of the boardlock 10 between the arms 30 and the legs 40.

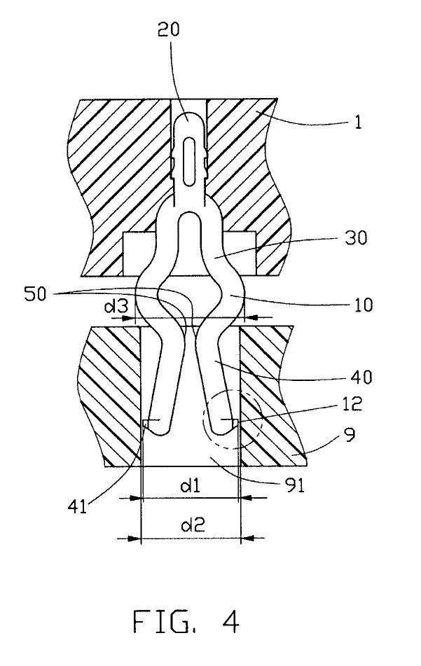

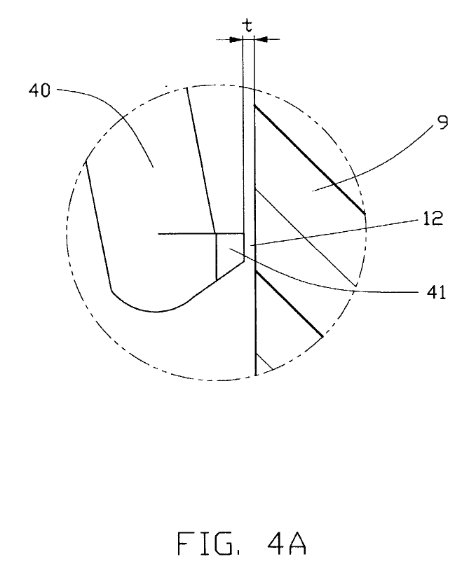

FIGS. 4-6 orderly illustrate an insertion process of the boardlock 10 into a boardlock receiving opening 91 of the printed circuit board 9.

Particularly referring to FIG. 4 in conjunction with FIG. 4A, the legs 40 of the boardlock 10 are partially received in the boardlock receiving opening 91. Importantly, a distance between the two tip portions 41 of the legs 40, which is designated as “d1”, is slightly smaller than a diameter of the boardlock receiving opening 91, which is designated as “d2”, so that clearance 12 is provided between the tip portions 41 and periphery wall of the boardlock receiving opening 91. Especially, a width of clearance 12 is designated as “t” which can be seen from FIG. 4A. Clearance 12 provides an important feature that the boardlock 10 can be inserted into the boardlock receiving opening 91 with zero insertion force. Meanwhile, a distance between the bowed portions 32 of the arms 30, which is designated as “d3”, is a little larger than the diameter of the boardlock receiving opening 91, which will be described in great detail hereinafter.

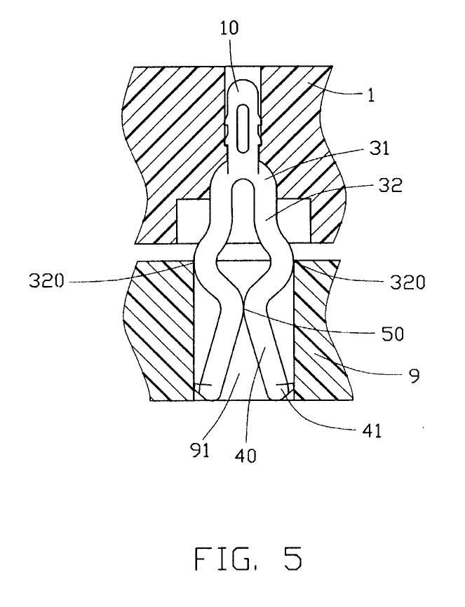

Turning to FIG. 5, when the boardlock 10 continues to be inserted into the boardlock receiving opening 91 with the tip portions 41 of the legs 40 arriving at a bottom of the board-lock receiving opening 91, the bowed portions 32 of the arms 30 are just received in a top of the boardlock receiving opening 91. It can be readily seen from FIG. 5 that the bowed portions 32 are slightly elastically deformed with the outer curved surfaces 320 abutting against a top of the opening 91. It causes the legs 40 to come together with the tip portions 41 thereof being bowed out and in turn causes the tip portions 41 moving to the periphery inner wall of the opening 91 and contacting thereon. Meanwhile, the two inner curved surfaces 50 of the boardlock 10 displace towards and finally contact with each other. In other words, a preload function of the boardlock 40 is achieved thereby. It should be noted that when the two inner curved surfaces 50 move toward each other, it is not necessary for the two inner curved surfaces 50 contacting with each other ultimately.

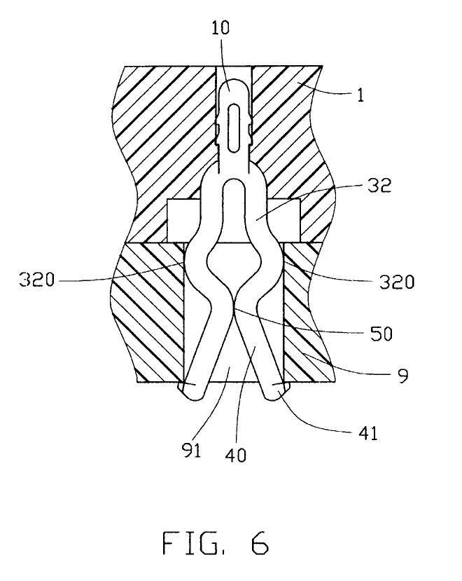

With reference to FIG. 6, which shows the boardlock 10 being substantially received in the boardlock receiving opening 91 so that firmly interlocking the electrical connector 1 with the printed circuit board 9. The preloaded tip portions 41 of the legs 40 are now snapped outward over the opening 91 and resisting against a bottom side of the printed circuit board 9.

Clearly, in the prefer embodiment, the diameter “d2” of the boardlock receiving opening 91 is larger than the distance “d1” between the tip portions 41 while smaller than the distance “d3” between the bowed portions 32. In a word, during the boardlock 10 entering into the boardlock receiving opening 91, the bowed portions 32 of the arms 30 are compressed by the peripheral wall of the opening 91 to enlarge the distance “d1” between the tip portions 41 of the legs 40, thus the tip portions 41 moves downwards along the peripheral wall of the opening 91, and finally moves outwards the opening 91 and abuts against a bottom of the printed circuit board 9.

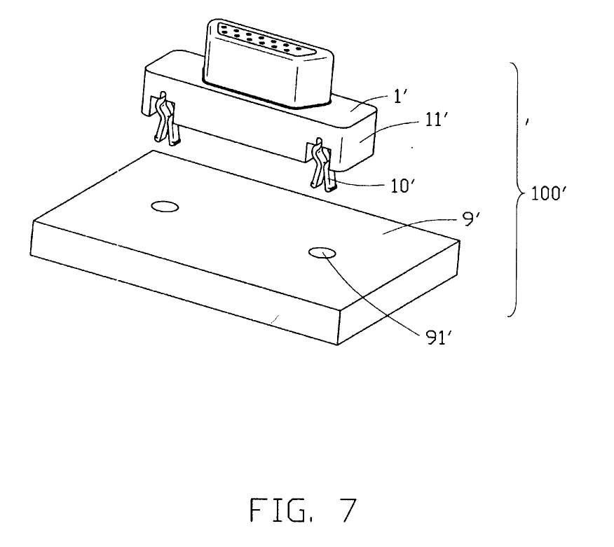

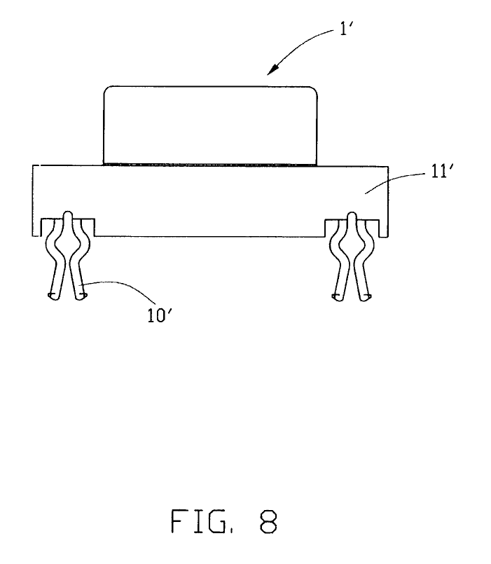

Together referring to FIGS. 7 and 8, the two figures detailedly illustrate a second embodiment of the represent invention. An electrical connector 1′ of a connector assembly 100′ comprises an insulating housing 11′ integrally formed with a pair of boardlocks 10′ which are oppositely positioned on a bottom face of the insulating housing 11′. The pair of boardlocks 10′ have a similar configuration with the boardlock 10 of the first embodiment and are received in respective boardlock receiving openings 91′ of a printed circuit board 9′ for interlocking the connector 1′ and the printed circuit board 9′ together.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

We claim:

1. A retention device comprising:
a first retention portion;
an actuating portion extending from the first retention portion, the actuating portion defining a first distance between two opposite outmost surfaces thereof; and
a second retention portion extending from the actuating portion in a direction away from the first retention portion, the second retention portion defining a second distance between two opposite outmost surfaces thereof;
wherein the second distance becomes larger when the actuating portion is compressed inwardly so that the second retention portion is adapted to engage with a member.

2. The retention device as claimed in claim 1, wherein the second distance is smaller than the first distance so that the second retention portion is able to be inserted into an opening whose dimension is larger than the second distance but smaller than the first distance by zero insertion force and the actuating portion can be compressed by peripheral wall of the opening to enlarge the second distance.

3. The retention device as claimed in claim 1, wherein the actuating portion is divided into two pieces confronting each other, and wherein the second retention portion is divided into two pieces each extending from a corresponding piece of the actuating portion.

4. The retention device as claimed in claim 3, wherein each piece of the actuating portion includes a curved portion on which the actuating portion is compressed.

5. An electrical connector comprising a housing portion having a bottom surface adapted for mounting onto a printed circuit board, and a pronged retention device downwardly extending from the bottom surface of the housing portion, the pronged retention device comprising a pair of arms confronting each other and an enlarged section at a middle section thereof, wherein tips of the pronged retention device move away from each other adapted to engage the printed circuit board when the enlarged section is compressed inwardly.

6. The electrical connector as claimed in claim 5, wherein said pronged retention device is integrally formed with said housing portion.

7. The electrical connector as claimed in claim 5, wherein said pronged retention device is made separately from said housing portion.

8. The electrical connector as claimed in claim 7, wherein said pronged retention device further comprises a housing retention portion for retaining said pronged retention device in said housing portion.

9. A boardlock for securing a board mounted connector onto a board, comprising:
a housing retention portion adapted for attaching to an insulating housing of said board mounted connector;
a compressible, intermediate portion extending from said housing retention portion and having bowed area formed therewith; and
a board retention portion extending from said compressible, intermediate portion and adapted for being received in a hole of said board, said board retention portion having a pair of legs each having an outwardly projected tip end;
wherein when said bowed area of said compressible intermediate portion are compressed in said hole of said board, said pair of legs are caused to come together which thereby bow out said outwardly projected tip ends.

10. The boardlock as described in claim 9, wherein said housing retention portion has a plurality of barbs formed therewith.

11. An electrical connector assembly, comprising:
a printed circuit board defining a hole thereon; and
an electrical connector mountable on said printed circuit board and having a boardlock attached thereon, said boardlock comprising:
a first retention portion secured on said electrical connector;
a second retention portion received in said hole of said printed circuit board, said second retention portion having spring means for being elastically received in said hole and detent means for locking said boardlock on said printed circuit board, said detent means having a pair of tip ends that are unattachedly/freely disposed within said hole of said printed circuit board until said spring means confronts and is compressed in said hole for essentially initial zero insertion force consideration.

12. The electrical connector assembly as claimed in claim 11, wherein said spring means of said second retention portion is configured as a pair of opposed bows and a diameter of said hole of said printed circuit board is larger than a distance between said pair of tip ends while smaller than a distance between said two bows when said spring means is in a relaxed manner.

13. The electrical connector assembly as claimed in claim 11, wherein the tip ends are exposed to and hooked with the printed circuit board around a lower circumferential edge of the hole, when said spring means is compressed in the hole.
